(19) United States
(12) Patent Application Publication
(10) Pub. No.: US 2024/0389386 A1
(43) Pub. Date: Nov. 21, 2024

(54) DISPLAY DEVICE AND MANUFACTURING METHOD FOR SAME

(71) Applicant: Samsung Display Co., Ltd., Yongin-Si (KR)

(72) Inventors: KYONG-CHOL LEE, Yongin-si (KR); DAESOO KIM, Yongin-si (KR); SANGGAB KIM, Yongin-si (KR); TAESUNG KIM, Yongin-si (KR); HYUNMIN CHO, Yongin-si (KR); DAEWON CHOI, Yongin-si (KR)

(21) Appl. No.: 18/656,470

(22) Filed: May 6, 2024

(30) Foreign Application Priority Data
May 16, 2023 (KR) 10-2023-0063299

(51) Int. Cl. H10K 59/121; G09G 3/3233; H10K 59/12

(52) U.S. Cl. CPC H10K 59/1213; H10K 59/1201; G09G 3/3233; G09G 2300/0819; G09G 2300/0852

(57) ABSTRACT

A display device is disclosed that includes a base layer, a light-emitting element, and a pixel circuit. The pixel circuit includes a first transistor, and the first transistor includes a metal oxide semiconductor pattern, a first gate having a plurality of conductive layers, and a gate insulation pattern. The uppermost layer among the plurality of conductive layers is divided into a first part adjacent to a drain region, a second part adjacent to a source region, and a third part between the first part and the second part. An upper surface of each of the first part and the second part may form a step with an upper surface of the third part. A sum of the widths of the upper surfaces of the first part and the second part may be smaller than the width of the upper surface of the third part.

### CROSS-REFERENCE TO RELATED APPLICATIONS

This U.S. non-provisional patent application claims priority under 35 U.S.C. § 119 of Korean Patent Application No. 10-2023-0063299, filed on May 16, 2023, the entire contents of which are hereby incorporated by reference.

### BACKGROUND

The present disclosure relates to a display device and a method of manufacturing the same, and more particularly, to a display device including an oxide transistor, and a method of manufacturing the same.

A display device includes a plurality of pixels and a driving circuit (for example, a scan driving circuit and a data driving circuit) for controlling the plurality of pixels. Each of the plurality of pixels includes a display element and a pixel circuit for controlling the display element. The pixel circuit may include a plurality of transistors organizationally connected.

The plurality of transistors may include a silicon semiconductor or a metal oxide semiconductor, and also include an electrode and lines. The lines included in the transistor may be formed by patterning through an etching process. Process gases provided during the etching process may remain on the patterned lines, and may cause corrosion of the lines. Therefore, various methods for preventing the corrosion of lines are being developed.

### SUMMARY

The present disclosure may provide a display device with improved reliability and display quality.

The present disclosure may also provide a method of manufacturing the display device.

An embodiment of a display device includes a base layer, a light-emitting element disposed on the base layer, and a pixel circuit disposed between the base layer and the light-emitting element, and electrically connected to the light-emitting element, wherein the pixel circuit may include a first transistor. Herein, the first transistor may include a metal oxide semiconductor pattern, a first gate, and a gate insulation pattern. The metal oxide semiconductor pattern may include a drain region, a source region, and a channel region disposed between the source region and the drain region. The first gate may be disposed on the metal oxide semiconductor pattern, overlap the channel region, and have a plurality of conductive layers. The gate insulation pattern may be disposed between the metal oxide semiconductor pattern and the first gate, and overlap the channel region. An uppermost layer among the plurality of conductive layers may be divided into a first part adjacent to the drain region, a second part adjacent to the source region, and a third part between the first part and the second part, each of an upper surface of the first part and an upper surface of the second part may form a step with an upper surface of the third part, and on a cross-section perpendicular to the base layer, a sum of widths of the upper surface of the first part and the upper surface of the second part in one direction may be smaller than a width of the upper surface of the third part in the one direction.

In an embodiment, a side surface of the first gate and a side surface of the gate insulation pattern may form a continuous slope.

In an embodiment, a thickness of the third part may be larger than a thickness of each of the first part and the second part.

In an embodiment, the first gate may include a first layer disposed on the gate insulation pattern, and including a first material, and a second layer disposed on the first layer, and including a second material different from the first material, the first material having a lower resistivity than the second material.

In an embodiment, the first material may contain aluminum, and the second material may contain titanium.

In an embodiment, the first gate may further include a third layer disposed between the gate insulation pattern and the first layer, and including a third material different from the first material, the third material having a higher resistivity than the first material.

In an embodiment, the first material may contain aluminum, and each of the second material and the third material may contain titanium.

In an embodiment, the first layer may have a larger thickness than the second layer and the third layer.

In an embodiment, the third part may include a first side surface adjacent to the first part and a second side surface adjacent to the second part, the first side surface may connect the upper surface of the first part and the upper surface of the third part, and the second side surface may connect the upper surface of the second part and the upper surface of the third part.

In an embodiment, the first transistor may further include a second gate, and the second gate may be disposed on a lower side of the metal oxide semiconductor pattern and electrically connected to the source region.

An embodiment of a method of manufacturing a display device includes forming at least one transistor on a base substrate. The forming of the at least one transistor may include forming a metal oxide semiconductor pattern on the base substrate, forming a preliminary insulation layer on the metal oxide semiconductor pattern, forming a conductive layer having an aluminum layer on the preliminary insulation layer, forming a photoresist pattern on the conductive layer, forming a first gate from the conductive layer by using a first etching gas containing a chlorine-based gas, forming a gate insulation pattern from the preliminary insulation layer by using a second etching gas different from the first etching gas, and performing a plasma surface treatment on the first gate, the gate insulation pattern, and the photoresist pattern.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram of a display device according to an embodiment of the inventive concept;

FIG. 2 is an equivalent circuit diagram of a pixel according to an embodiment of the inventive concept;

FIG. 3 is a cross-sectional view of a display panel according to an embodiment of the inventive concept;

FIG. 4 is a cross-sectional view of a transistor according to an embodiment of the inventive concept;

FIGS. 5A and 5B are cross-sectional views each illustrating a partial configuration included in a transistor according to an embodiment of the inventive concept;

FIGS. 6A to 6D are cross-sectional views sequentially illustrating some operations of a method of manufacturing a display device according to an embodiment of the inventive concept;

FIG. 7 is a plan view of a manufacturing process system used in manufacturing a display device according to an embodiment;

FIGS. 8A to 8C are images showing TiFₓ contamination evaluation results of a Comparative Example and an Example;

FIGS. 9A and 9B are graphs showing leakage current evaluation results of the Comparative Example and the Example; and

FIGS. 10A and 10B are images showing bright spot defect evaluation results of the Comparative Example and the Example.

### DETAILED DESCRIPTION

Embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

It will be understood that, although the terms first, second, etc. may be used herein to describe various elements, components, regions, layers or sections, these elements, components, regions, layers or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “comprises,” “includes,” and “have” (as well as their variations such as comprising), when used in this specification, specify the presence of stated features, integers, steps, operations, elements, components, or groups thereof, but do not preclude the presence or addition of one or more other features, integers, steps, operations, elements, components, or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

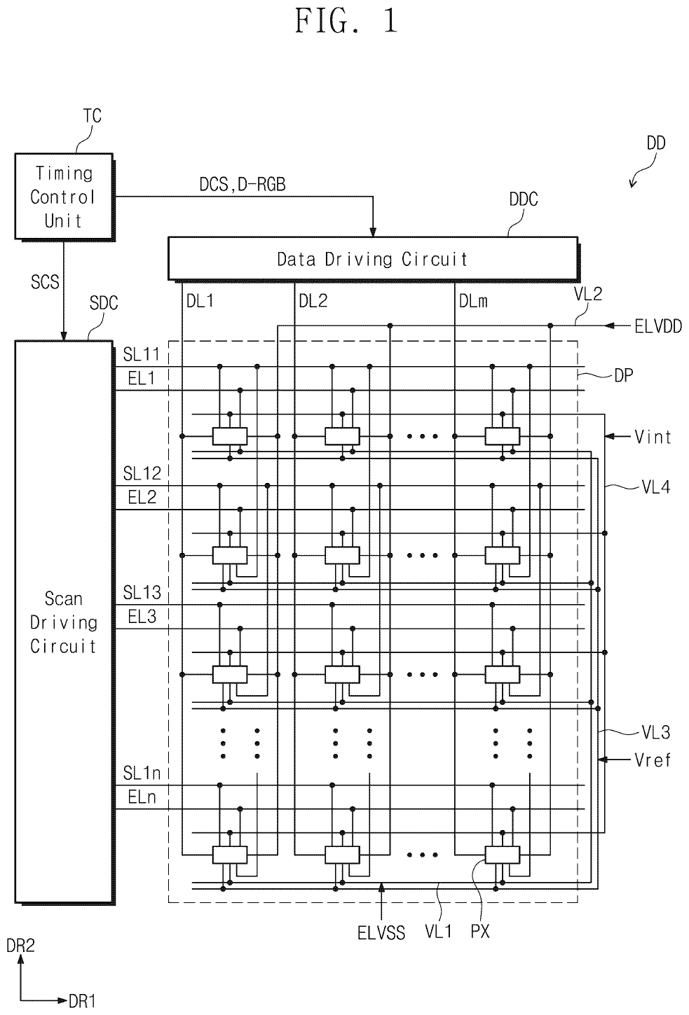

FIG. 1 is a block diagram of a display device DD according to an embodiment of the inventive concept. The display device DD includes a timing control unit TC, a scan driving circuit SDC, a data driving circuit DDC, and a display panel DP. In this embodiment, the display panel DP is illustrated as an emission-type display panel. The emission-type display panel may include an organic light-emitting display panel or an inorganic light-emitting display panel.

The timing control unit TC receives input image signals, converts the input image signals, so that the data format thereof is compatible with interface specifications of the scan driving circuit SDC, and thus generates image data D-RGB. The timing control unit TC outputs the image data D-RGB and various control signals DCS and SCS.

The scan driving circuit SDC receives a scan control signal SCS from the timing control unit TC. The scan control signal SCS may include a vertical start signal for starting an operation of the scan driving circuit SDC, a clock signal for determining output timing of signals, etc. The scan driving circuit SDC generates a plurality of scan signals, and sequentially outputs the signals through corresponding scan signal lines SL11 to SL1n. In addition, the scan driving circuit SDC generates a plurality of emission control signals in response to the scan control signal SCS, and outputs the plurality of emission control signals through corresponding emission signal lines EL1 to ELn.

FIG. 1 illustrates that the plurality of scan signals and the plurality of emission control signals are output from one scan driving circuit SDC, but an embodiment of the inventive concept is not limited thereto. According to an embodiment of the inventive concept, the display device DD may include a plurality of scan driving circuits. In addition, according to an embodiment of the inventive concept, a driving circuit for generating the plurality of scan signals to output, and a driving circuit for generating the plurality of emission control signals to output may be formed separately.

The data driving circuit DDC receives a data control signal DCS and the image data D-RGB from the timing control unit TC. The data driving circuit DDC converts the image data D-RGB into data signals, and outputs the data signals through a plurality of data lines DL1 to DLm to be described later. The data signals are analog voltages corresponding to grayscale values of the image data D-RGB.

The display panel DP may include a plurality of groups of scan lines. FIG. 1 exemplarily illustrates first-group scan signal lines SL11 to SL1n. The emission-type display panel DP includes the emission signal lines EL1 to ELn, the data lines DL1 to DLm, a first voltage line VL1, a second voltage line VL2, a third voltage line VL3, a fourth voltage line VLA, and a plurality of pixels PX.

The first-group scan signal lines SL11 to SL1n may extend in a first direction DR1, and may be arranged in a second direction DR2 crossing the first direction DR1. The data lines DL1 to DLm may cross the first-group scan signal lines SL11 to SL1n.

The first voltage line VL1 receives a first power voltage ELVSS. The second voltage line VL2 receives a second power voltage ELVDD. The second power voltage ELVDD has a higher level than the first power voltage ELVSS. The third voltage line VL3 receives a reference voltage Vref (hereinafter, a first voltage). The fourth voltage line VL4 receives an initialization voltage Vint (hereinafter, a second voltage). The first voltage Vref has a lower level than the second power voltage ELVDD. The second voltage Vint has a lower level than the second power voltage ELVDD. In this embodiment, the second voltage Vint may have a lower level than the first voltage Vref and the first power voltage ELVSS.

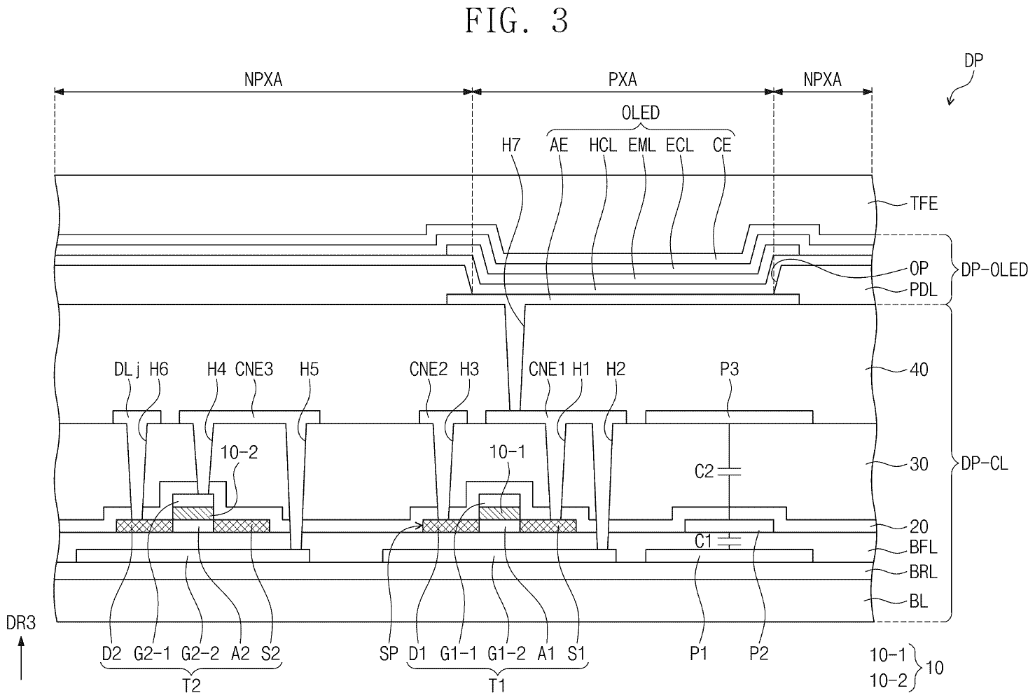

At least one of the first voltage line VL1, the second voltage line VL2, the third voltage line VL3, or the fourth voltage line VL4 may include at least one of a line extending in the first direction DR1 or a line extending in the second direction DR2. Despite being disposed on different layers among a plurality of insulation layers 10 to 30 illustrated in FIG. 3, the line extending in the first direction DR1 and the line extending in the second direction DR2 of the voltage line may be electrically connected to each other.

As above, the display device DD according to an embodiment has been described with reference to FIG. 1, but the display device DD according to an embodiment of the inventive concept is not limited thereto. The signal lines may be further added, or omitted, according to the configuration of a pixel circuit. In addition, the relationship of electrical connection between a pixel PX and the signal lines may be changed.

A plurality of pixels PX may include a plurality of groups for generating different color light. For example, red pixels that generate red color light, green pixels that generate green color light, and blue pixels that generate blue color light may be included. A light-emitting element of the red pixel, a light-emitting element of the green pixel, and a light-emitting element of the blue pixel may include light-emitting layers formed of different materials.

The pixel circuit may include a plurality of transistors and at least one capacitor. At least one of the scan driving circuit SDC or the data driving circuit DDC may include the plurality of transistors formed through the same process as that of the pixel circuit.

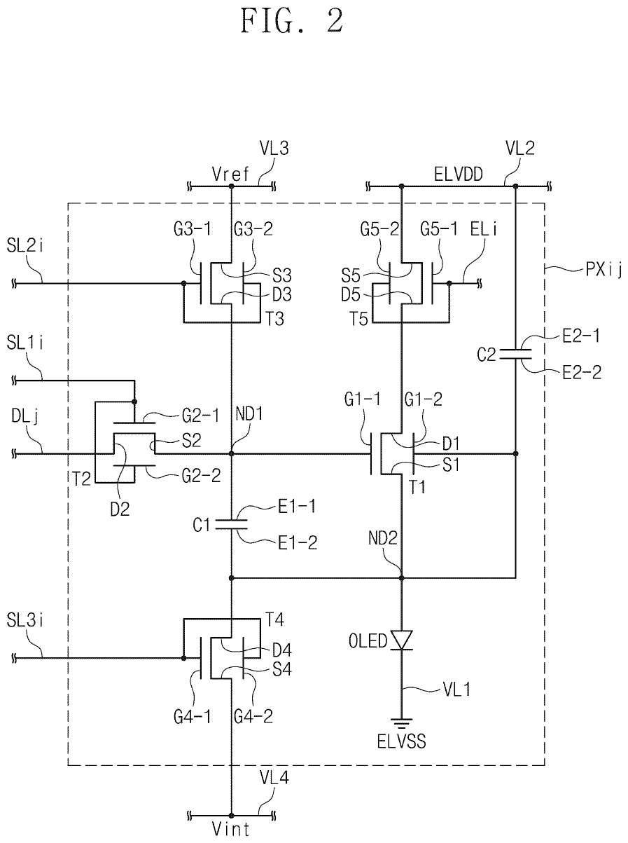

FIG. 2 is an equivalent circuit diagram of a pixel PXij according to an embodiment of the inventive concept. FIG. 2 representatively illustrates the pixel PXij connected to an i-th scan line SLli (or a first scan line) among the first-group scan lines SL11 to SL1n (see FIG. 1), and connected to a j-th data line DLj (or a first data line) among the plurality of data lines DL1 to DLm (see FIG. 1). The pixel PXij is connected to an i-th scan line SL2i among second-group scan lines, and connected to an i-th scan line SL3i among third-group scan lines.

In this embodiment, a pixel circuit may include first to fifth transistors T1 to T5, a first capacitor C1, a second capacitor C2, and a light-emitting element OLED. In this embodiment, the first to fifth transistors T1 to T5 are described as N-type transistors. However, an embodiment of the inventive concept is not limited thereto, and at least one of the first to fifth transistors T1 to T5 may be a P-type transistor. In addition, according to an embodiment of the inventive concept, at least one of the first to fifth transistors T1 to T5 may be omitted, or an additional transistor may further be included in the pixel PXij.

In this embodiment, it is illustrated that each of the first to fifth transistors T1 to T5 includes two gates, but at least one transistor may include only one gate. It is illustrated that respective upper gates G2-1, G3-1, G4-1, and G5-1 and respective lower gates G2-2, G3-2, G4-2, and G5-2 of the second to fifth transistors T2 to T5 are electrically connected to each other, but an embodiment of the inventive concept is not limited thereto. The respective lower gates G2-2, G3-2, G4-2, and G5-2 of the second to fifth transistors T2 to T5 may be floating electrodes.

In this embodiment, the first transistor T1 may be a driving transistor, and the second transistor T2 may be a switching transistor. A node to which a gate G1-1 (hereinafter, a first gate or first upper gate) of the first transistor T1 is connected may be defined as a first node ND1, and a node to which a source S1 of the first transistor T1 is connected may be defined as a second node ND2.

A light-emitting element OLED includes a first electrode electrically connected to the second node ND2, a second electrode that receives a first power voltage ELVSS, and a light-emitting layer disposed between the first electrode and the second electrode. The light-emitting element OLED will be described in detail later.

The first transistor Tl is electrically connected between a second voltage line VL2, which receives a second power voltage ELVDD, and the second node ND2. The first transistor T1 may include a source S1 (or a first source) connected to the second node ND2, a drain D1 (or a first drain), a channel region (or a semiconductor region), and the first upper gate G1-1. The first upper gate G1-1 may be electrically connected to the first node ND1. The first transistor T1 may further include a gate G1-2 (hereinafter, a first lower gate) connected to the second node ND2. The first transistor T1 controls a drive current of the light-emitting element OLED on the basis of the charging capacity of a first capacitor C1.

The second transistor T2 is electrically connected between the j-th data line DLj and the first node ND1. The second transistor T2 may include a source S2 (or a second source) connected to the first node ND1, a drain D2 (or a second drain) connected to the j-th data line DLj, a channel region, and a gate G2-1 (hereinafter, a second upper gate) connected to the first-group i-th scan line SL1i. The second transistor T2 may further include a gate G2-2 (hereinafter, a second lower gate) electrically connected to the second upper gate G2-1. The third to fifth transistors T3 to T5, to be described later, may include the upper gates G3-1, G4-1, and G5-1 and the lower gates G3-2, G4-2, and G5-2 respectively corresponding to the second upper gate G2-1 and the second lower gate G2-2. The second transistor T2 provides a data voltage to the first capacitor C1.

The third transistor T3 is electrically connected between the first node ND1 and a third voltage line VL3 which receives a first voltage Vref. The third transistor T3 may include a drain D3 (hereinafter, a third drain) connected to the first node ND1, a source S3 (hereinafter, a third source) connected to the third voltage line VL3, a channel region, and the third upper gate G3-1 connected to the second-group i-th scan line SL2i. The third transistor T3 may further include the third lower gate G3-2 electrically connected to the third upper gate G3-1.

The fourth transistor T4 is electrically connected between a fourth voltage line VL4, which receives a second voltage Vint, and the second node ND2. The fourth transistor T4 may include a drain D4 (hereinafter, a fourth drain) connected to the second node ND2, a source S4 (hereinafter, a fourth source) connected to the fourth voltage line VL4, a channel region, and the fourth upper gate G4-1 connected to the third-group i-th scan line SL3i. The fourth transistor T4 may further include the fourth lower gate G4-2 electrically connected to the fourth upper gate G4-1.

The fifth transistor T5 is electrically connected between the second voltage line VL2 and the first drain D1 or the first source S1. In this embodiment, the fifth transistor T5 may include a source S5 (hereinafter, a fifth source) connected to the second voltage line VL2, a drain D5 (hereinafter, a fifth drain) connected to the first drain D1, a channel region, and the fifth upper gate G5-1 connected to an i-th emission signal line ELi. The fifth transistor T5 may further include the fifth lower gate G5-2 electrically connected to the fifth upper gate G5-1.

The first capacitor C1 is electrically connected between the first node ND1 and the second node ND2. The first capacitor C1 includes a first electrode E1-1 connected to the first node ND1, and a second electrode E1-2 connected to the second node ND2.

The second capacitor C2 is electrically connected between the second voltage line VL2 and the second node ND2. The second capacitor C2 includes a first electrode E2-1 connected to the second voltage line VL2, and a second electrode E2-2 connected to the second node ND2.

FIG. 3 is a cross-sectional view of a display panel DP according to an embodiment of the inventive concept. FIG. 3 illustrates a cross-section of a portion corresponding to a partial configuration of the pixel PXij illustrated in FIG. 2.

Referring to FIG. 3, the display panel DP may include a circuit element layer DP-CL, a display element layer DP-OLED, and an encapsulation layer TFE. The display panel DP may further include functional layers such as an anti-reflection layer, a refractive index control layer, or the like. The circuit element layer DP-CL includes at least a plurality of insulation layers and a circuit element. The insulation layers, to be described as follows, may include an organic layer or inorganic layer.

The insulation layer, a semiconductor layer, and a conductive layer are formed through a coating process, a deposition process, etc. After this, the insulation layer, the semiconductor layer, and the conductive layer may be selectively patterned through photolithography and an etching process. Through these processes, a semiconductor pattern, a conductive pattern, a signal line, etc. are formed. Patterns disposed on the same layer may be formed through the same process.

A base layer BL may include a synthetic resin layer. The synthetic resin layer may include a thermosetting rein. In particular, the synthetic resin layer may be a polyimide-based resin layer, and the material is not particularly limited. The synthetic resin layer may include at least one of an acrylate-based resin, a methacrylate-based resin, polyisoprene, a vinyl-based resin, an epoxy-based resin, a urethane-based resin, a cellulose-based resin, a siloxane-based resin, a polyamide-based resin, or a perylene-based resin. In addition, the base layer BL may include a glass substrate, a metal substrate, an organic/inorganic composite material substrate, or the like. The base layer BL may include a first polyimide layer, a second polyimide layer, and an inorganic layer disposed therebetween.

At least one inorganic layer is formed on an upper surface of the base layer BL. The inorganic layer may include at least one of aluminum oxide, titanium oxide, silicon oxide, silicon nitride, silicon oxynitride, zirconium oxide, or hafnium oxide. The inorganic layer may be formed of multiple layers. The multi-layer inorganic layers may be composed of a barrier layer BRL or a buffer layer BFL to be described later. The barrier layer BRL and the buffer layer BFL may be selectively disposed.

The barrier layer BRL prevents foreign substances from entering from the outside. The barrier layer BRL may include a silicon oxide layer and a silicon nitride layer. Each of the layers may be provided in plurality, and the silicon oxide layers and the silicon nitride layers may be alternately stacked.

The conductive layer (hereinafter, a first conductive layer) is disposed on the barrier layer BRL. The first conductive layer may include a plurality of conductive patterns. FIG. 3 illustrates some patterns of the first conductive layer. A first lower gate G1-2, a second lower gate G2-2, and a first conductive pattern P1 are illustrated as examples of the conductive pattern included in the first conductive layer.

The first conductive pattern P1 defines the first electrode E1-1 of the first capacitor C1 illustrated in FIG. 2. FIG. 3 illustrates that the first conductive pattern P1 and the first upper gate G1-1 are spaced apart from each other, but the first conductive pattern P1 and the first upper gate G1-1 may be electrically connected to each other. The first conductive pattern P1 and the first lower gate G1-2 may be connected to each other through the conductive pattern disposed on a different layer, or may have an integral shape on a plane. The first lower gate G1-2 may be electrically connected to the second electrode E1-2 of the first capacitor C1. Meanwhile, in this specification, the first lower gate G1-2 may be referred to as a second gate.

The buffer layer BFL may be disposed on the barrier layer BRL to cover the first lower gate G1-2, the second lower gate G2-2, and the first conductive pattern P1. The buffer layer BFL improves bonding forces between the base layer BL and the semiconductor pattern or the conductive pattern. The buffer layer BFL may include at least one of a silicon oxide layer or a silicon nitride layer. When the buffer layer BFL includes both of the silicon oxide layer and the silicon nitride layer, the silicon oxide layer and the silicon nitride layer may be alternately stacked.

The semiconductor layer is disposed on the buffer layer BFL. The semiconductor layer may include a plurality of semiconductor patterns. In this embodiment, the semiconductor pattern may be a metal oxide semiconductor pattern SP. The metal oxide semiconductor pattern SP may include a crystalline or amorphous oxide semiconductor. For example, the metal oxide semiconductor pattern SP may include an oxide of metal such as zinc (Zn), indium (In), gallium (Ga), tin (Sn), and titanium (Ti), or a mixture of metal, such as zinc (Zn), indium (In), gallium (Ga), tin (Sn), and titanium (Ti), and an oxide thereof. The metal oxide semiconductor may include indium-tin oxide (ITO), indium-gallium-zinc oxide (IGZO), zinc oxide (ZnO), zinc-indium oxide (ZIO), indium oxide (InO), titanium oxide (TiO), indium-zinc-tin oxide (IZTO), zinc-tin oxide (ZTO), etc.

The metal oxide semiconductor pattern SP may include a plurality of regions distinguished depending on whether the metal oxide is reduced or not. A region where the metal oxide is reduced (hereinafter, a reduced region) has higher conductivity than a region where the metal oxide is unreduced (hereinafter, an unreduced region). The reduced region serves substantially as a source region, a drain region, or a signal transmission region of a transistor. The unreduced region substantially corresponds to a channel region (or a semiconductor region or unreduced region) of the transistor. In other words, a portion of the semiconductor pattern may be a channel region of a transistor, and another portion may be a source region or drain region of the transistor, and another portion may be a signal transmission region.

Substantially, a first upper gate G1-1, to be described later, defines a channel region A1 of a first transistor T1, and a second upper gate G2-1, to be described later, defines a channel region A2 of a second transistor T2. The length of the channel region A1 of the first transistor T1 may be determined to correspond to the width of the first upper gate G1-1, and the length of the channel region A2 of the second transistor T2 may be determined to correspond to the width of the second upper gate G2-1.

The source region or the drain region itself may be the source or the drain of each of the transistors T1 to T5 described with reference to FIG. 2. The source or the drain of the transistors T1 to T5 may include a source region or a drain region of the previously described semiconductor pattern, and the conductive pattern connected thereto. Hereinafter, for the convenience of description, the source region or drain region of the metal oxide semiconductor pattern SP will be referred to as a source or drain, respectively.

As illustrated in FIG. 3, the first transistor T1 includes the metal oxide semiconductor pattern SP having a source S1, a channel region A1, and a drain D1. The source S1 and the drain D1 of the first transistor T1 extend in opposite directions from the channel region A1. A source S2, a channel region A2, and a drain D2 of the second transistor T2 are also formed from the metal oxide semiconductor pattern.

The aforementioned first lower gate G1-2 and second lower gate G2-2 may have a function of a light-blocking pattern. The first lower gate G1-2 and the second lower gate G2-2 may be disposed respectively on lower sides of the channel region A1 of the first transistor T1 and the channel region A2 of the second transistor T2, and may thus block light incident thereto from the outside. The light-blocking pattern prevents external light from changing voltage-current characteristics of each of the first transistor T1 and the second transistor T2.

A second conductive pattern P2 overlapping the first conductive pattern P1 in a thickness direction DR3 may be disposed on the buffer layer BFL. The second conductive pattern P2 defines the second electrode E1-2 of the first capacitor C1 and the second electrode E2-2 of the second capacitor C2 illustrated in FIG. 2.

A first insulation layer 10 is disposed on the buffer layer BFL. In this embodiment, the first insulation layer 10 is not formed on the entire region of the display panel DP, and overlaps only the channel region of the transistor. However, an embodiment of the inventive concept is not limited thereto, and the first insulation layer 10 may also overlap a particular conductive pattern to be described later. The first insulation layer 10 may include a plurality of insulation patterns. FIG. 3 exemplarily illustrates a first insulation pattern 10-1 and a second insulation pattern 10-2. Unlike what is illustrated in FIG. 3, according to an embodiment of the inventive concept, the first insulation layer 10 may not be patterned. At this time, the first insulation layer 10 may cover the metal oxide semiconductor pattern SP. The first insulation pattern 10-1 and the second insulation pattern 10-2 respectively overlap the first upper gate G1-1 and the second upper gate G2-1 to be described later. In addition, although not illustrated in the drawing, an insulation pattern overlapping the second conductive pattern P2 may also be disposed on the buffer layer BFL.

A conductive layer (hereinafter, a second conductive layer) is disposed on the first insulation layer 10. The second conductive layer may include a plurality of conductive patterns each overlapping the first insulation layer 10. FIG. 3 illustrates the first upper gate G1-1 and the second upper gate G2-1 as an example of the conductive pattern of the second conductive layer. An edge of the conductive pattern of the second conductive layer and an edge of the insulation pattern of the first insulation layer 10, which overlap each other on a plane, may be aligned. That is, a side surface of the conductive pattern of the second conductive layer and a side surface of the insulation pattern of the first insulation layer 10 may form a continuous slope. For example, the edge of the first upper gate G1-1 and the edge of the first insulation pattern 10-1 may be aligned, and the edge of the second upper gate G2-1 and the edge of the second insulation pattern 10-2 may be aligned.

A second insulation layer 20 that covers the first upper gate G1-1, the second upper gate G2-1, and the second conductive pattern P2 is disposed on the buffer layer BFL. The second insulation layer 20 may be an inorganic layer or an organic layer, and may have a single-layer or multi-layer structure. The second insulation layer 20 may cover the source SI and the drain D1 of the first transistor T1, and cover the source S2 and the drain D2 of the second transistor T2. The second insulation layer 20 may cover a side surface of each of the first insulation pattern 10-1 and the second insulation pattern 10-2.

A third insulation layer 30 is disposed on the second insulation layer 20. In this embodiment, the third insulation layer 30 may be an organic layer. The third insulation layer 30 may have a single-layer structure, but the structure is not particularly limited. The third insulation layer 30 may also have a multi-layer structure. In an embodiment, the thickness of the third insulation layer 30 may be larger than the thickness of the second insulation layer 20, but an embodiment of the inventive concept is not limited thereto.

A conductive layer (hereinafter, a third conductive layer) is disposed on the third insulation layer 30. The third conductive layer may include a plurality of conductive patterns. The third conductive layer may include a plurality of connection electrodes CNE1, CNE2, and CNE3, a first data line DLj, and a third conductive pattern P3.

The first connection electrode CNE1 may be connected to the source S1 of the first transistor T1 through a first contact hole H1 passing through the second and third insulation layers 20 and 30, and may be connected to the first lower gate G1-2 through a second contact hole H2 passing through the buffer layer BFL, and the second and third insulation layers 20 and 30. The second connection electrode CNE2 is connected to the drain D1 of the first transistor T1 through a third contact hole H3 passing through the second and third insulation layers 20 and 30. The third connection electrode CNE3 is connected to the second upper gate G2-1 through a fourth contact hole H4 passing through the second and third insulation layers 20 and 30, and connected to the second lower gate G2-2 through a fifth contact hole H5 passing through the buffer layer BFL, and the second and third insulation layers 20 and 30.

The first data line DLj is connected to the second drain D2 through a sixth contact hole H6 passing through the second and third insulation layers 20 and 30. The third conductive pattern P3 defines the first electrode E2-1 of the second capacitor C2 illustrated in FIG. 2.

A fourth insulation layer 40 covering the third conductive layer is disposed on the third insulation layer 30. In this embodiment, the fourth insulation layer 40 may be an organic layer, and may have a single-layer structure, but is not particularly limited thereto. The fourth insulation layer 40 may also have a multi-layer structure.

A light-emitting element OLED and a pixel-defining film PDL may be disposed on the fourth insulation layer 40. The light-emitting element OLED may include a first electrode AE, a hole control layer HCL, a light-emitting layer EML, an electron control layer ECL, and a second electrode CE.

The first electrode AE of the light-emitting element OLED is disposed on the fourth insulation layer 40. The first electrode AE may be an anode. The pixel-defining film PDL is disposed on the fourth insulation layer 40. The first electrode AE is connected to the first connection electrode CNE1 through a seventh contact hole H7 passing through the fourth insulation layer 40.

An opening OP of the pixel-defining film PDL extends to at least a portion of the first electrode AE. The opening OP of the pixel-defining film PDL may define a light-emitting region PXA. For example, the plurality of pixels PX (see FIG. 1) may be disposed in a particular rule on a flat surface of the display panel DP (see FIG. 1). A region where the plurality of pixels PX are disposed may be defined as a pixel region, and one pixel region may include a light-emitting region PXA and a non-light-emitting region NPXA adjacent to the light-emitting region PXA. The non-light-emitting region NPXA may surround the light-emitting region PXA.

The hole control layer HCL is disposed on the first electrode AE. The hole control layer HCL may be disposed in the light-emitting region PXA and the non-light-emitting region NPXA in common. A common layer, such as the hole control layer HCL, may be formed across the plurality of pixels PX in common. The hole control layer HCL may include a hole transport layer and a hole injection layer. In addition, the hole control layer HCL may further include an electron blocking layer.

The light-emitting layer EML is disposed on the hole control layer HCL. The light-emitting layer EML may be disposed only in a region corresponding to the opening OP. The light-emitting layer EML may be formed to be separated for each of the plurality of pixels PX (see FIG. 1). In this embodiment, the patterned light-emitting layer EML is exemplarily illustrated, but the light-emitting layer EML may be disposed in the light-emitting region PXA and in the non-light-emitting region NPXA in common. The light-emitting layer EML, disposed in common, may generate white light or blue light. In addition, the light-emitting layer EML may have a multi-layer structure.

The electron control layer ECL is disposed on the light-emitting layer EML. The electron control layer ECL may include an electron transport layer and an electron injection layer. In addition, the electron control layer ECL may further include a hole blocking layer. The second electrode CE is disposed on the electron control layer ECL. The electron control layer ECL and the second electrode CE are disposed in the light-emitting region PXA and the non-light-emitting region NPXA in common.

The encapsulation layer TFE is disposed on the second electrode CE. The encapsulation layer TFE is disposed in the light-emitting region PXA and the non-light-emitting region NPXA in common. In this embodiment, the encapsulation layer TFE directly covers the second electrode CE. According to an embodiment of the inventive concept, a capping layer that directly covers the second electrode CE may further be disposed. According to an embodiment of the inventive concept, the stacked structure of the light-emitting element OLED may also have a structure in which the structure illustrated in FIG. 3 is inverted upside down.

The encapsulation layer TFE includes an inorganic layer or organic layer. The encapsulation layer TFE may include at least one inorganic layer and at least one organic layer. According to an embodiment of the inventive concept, the encapsulation layer TFE may include two inorganic layers and one organic layer disposed therebetween. According to an embodiment of the inventive concept, the encapsulation layer TFE may include a plurality of inorganic layers and a plurality of organic layers alternately stacked.

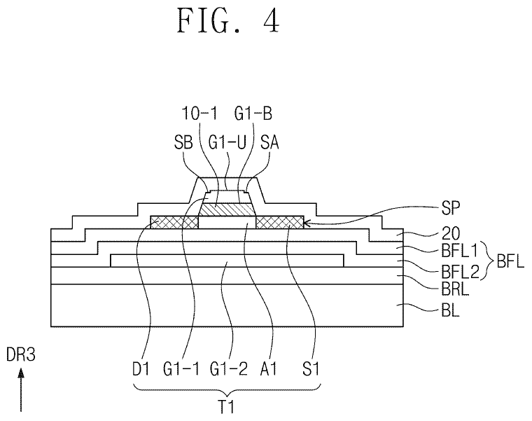

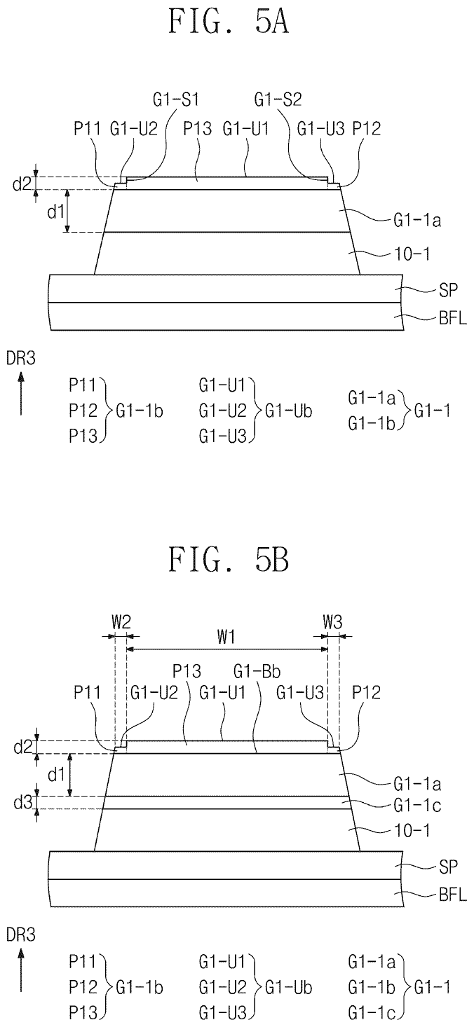

FIG. 4 is a cross-sectional view of a transistor according to an embodiment of the inventive concept. FIGS. 5A and 5B are cross-sectional views each illustrating a partial configuration included in a transistor according to an embodiment of the inventive concept. FIG. 4 illustrates a cross-sectional view corresponding to the first transistor T1 in FIG. 3. FIGS. 5A and 5B illustrate enlarged views of a first upper gate G1-1 (hereinafter, a first gate) included in the first transistor T1 in FIG. 4.

Referring to FIG. 4, a buffer layer BFL may include a first buffer layer BFL1, and further include a second buffer layer BFL2. For example, the buffer layer BFL may include the first buffer layer BFL1 disposed on a barrier layer BRL, and further include the second buffer layer BFL2 disposed between the barrier layer BRL and the first buffer layer BFL1. In an embodiment, the first buffer layer BFL1 may be a silicon oxide layer, and the second buffer layer BFL2 may be a silicon nitride layer.

A metal oxide semiconductor pattern SP of the first transistor T1 may be disposed on the buffer layer BFL. The metal oxide semiconductor pattern SP may be disposed on the first buffer layer BFL1 that is a silicon oxide layer. A source S1, a channel region A1, and a drain D1 of the first transistor T1 may be formed from the metal oxide semiconductor pattern SP. The source S1 and the drain D1 may extend in opposite directions from the channel region A1 on a cross-section.

A first insulation pattern 10-1 may be disposed on the buffer layer BFL. The first insulation pattern 10-1 overlaps at least a portion of the metal oxide semiconductor pattern SP. The first insulation pattern 10-1 may overlap the channel region A1 of the metal oxide semiconductor pattern SP. The first insulation pattern 10-1 may include at least one of aluminum oxide, titanium oxide, silicon oxide, silicon nitride, silicon oxynitride, zirconium oxide, or hafnium oxide. For example, the first insulation pattern 10-1 may include silicon oxide (SiOₓ). The first insulation pattern 10-1 may be referred to as a gate insulation pattern.

The first upper gate G1-1 is disposed on the first insulation pattern 10-1. The first upper gate G1-1 overlaps at least a portion of the metal oxide semiconductor pattern SP. For example, the first upper gate G1-1 overlaps the channel region A1 of the metal oxide semiconductor pattern SP.

The first upper gate G1-1 may include a lower surface G1-B adjacent to the first insulation pattern 10-1, and an upper surface G1-U opposed to the lower surface G1-B and spaced apart from the first insulation pattern 10-1. The lower surface G1-B of the first upper gate G1-1 may be a surface in contact with the first insulation pattern 10-1. The upper surface G1-U of the first upper gate G1-1 may form steps SA and SB.

The first upper gate G1-1 may include a plurality of conductive layers stacked in the thickness direction DR3. The first upper gate G1-1 may have the steps SA and SB on the uppermost layer among the plurality of conductive layers. The first upper gate G1-1 may form the steps SA and SB on an upper surface of the uppermost layer among the plurality of conductive layers. The steps SA and SB of the first upper gate G1-1 may be formed on edges of the first upper gate G1-1 in an etching process to be described later. The uppermost layer of the first upper gate G1-1 may be a layer disposed farthest from the first insulation pattern 10-1 among the plurality of conductive layers included in the first upper gate G1-1. Meanwhile, the lowermost layer of the first upper gate G1-1 may be a layer adjacent to the first insulation pattern 10-1 among the plurality of conductive layers included in the first upper gate G1-1.

On a cross-section, the uppermost layer of the first upper gate G1-1 may have a first step SA at a position adjacent to the source S1, and have a second step SB at a position adjacent to the drain D1. The first step SA and the second step SB that are formed in the same etching process of the first upper gate G1-1 may have substantially the same shape.

The second insulation layer 20 is disposed on the first insulation pattern 10-1, and covers the first upper gate G1-1. The second insulation layer 20 covers the first upper gate G1-1 tightly without lifting at portions of the first step SA and the second step SB. The second insulation layer 20 may include at least one of aluminum oxide, titanium oxide, silicon oxide, silicon nitride, silicon oxynitride, zirconium oxide, or hafnium oxide, but an embodiment of the inventive concept is not limited thereto.

FIG. 5A exemplarily illustrates the first upper gate G1-1 including two conductive layers, and FIG. 5B exemplarily illustrates the first upper gate G1-1 including three conductive layers.

Referring to FIG. 5A, the first upper gate G1-1 may include a first layer G1-1a disposed on the first insulation pattern 10-1, and a second layer G1-1b disposed above the first layer G1-1a. In addition, the first upper gate G1-1 may further include a conductive layer disposed under the first layer G1-1a. For example, the first upper gate G1-1 may further include a third layer G1-1c under the first layer G1-1a as illustrated in FIG. 5B. The third layer G1-1c may be disposed between the first layer G1-1a and the first insulation pattern 10-1.

The first layer G1-1a may include a first material having conductivity. The first layer G1-1a may have lower electrical resistance than the second layer G1-1b and the third layer G1-1c. The first layer G1-1a may have a resistance of about 0.5 Ω or less. For example, the first material may include aluminum (Al). The first layer G1-1a may be an aluminum layer, but an embodiment of the inventive concept is not limited thereto.

The conductivity of the first layer G1-1a may substantially determine the conductivity of the first upper gate G1-1. Therefore, as the material constituting the first layer G1-1a has a lower resistivity, the first upper gate G1-1 with low-resistance characteristics may be formed. According to an embodiment of the inventive concept, through the low-resistance characteristics of the first upper gate G1-1, high-speed driving of the display panel DP (see FIG. 1) may be possible, and RC delay may be easily overcome, and thus, providing a high-resolution display panel DP (see FIG. 1) may be possible. Consequently, display characteristics of the display device DD (see FIG. 1) may be improved, and power consumption may be reduced.

The second layer G1-1b may be disposed on the first layer G1-1a. The second layer G1-1b includes a second material. The second material may have conductivity. The second material may be different from the first material. The second material may be relatively higher in rigidity than the first material. The second layer G1-1b may block the first layer G1-1a from contact by an etching gas during a dry etching process for forming contact holes (for example, H1, H2, and H3 in FIG. 3). Accordingly, damages to the first layer G1-1a may be prevented. The second material may have higher corrosion resistance for the etching gas than the first material. For example, when the etching gas is fluorine-based, and the first layer G1-1a includes aluminum, the second layer G1-1b may include titanium (Ti), but an embodiment of the inventive concept is not limited thereto. The thickness of the second layer G1-1b may be smaller than the thickness of the first layer G1-1a.

The third layer G1-1c is disposed under the first layer G1-1a. The third layer G1-1c may be disposed apart from the second layer G1-1b with the first layer G1-1a therebetween. In an embodiment, when the first upper gate G1-1 includes the first to third layers G1-1a, G1-1b, and G1-1c, the third layer G1-1c may be disposed adjacent to the metal oxide semiconductor pattern SP and may be in contact with the first insulation pattern 10-1. The third layer G1-1c includes a third material. The third material may have conductivity. The third material may be different from the first material, and same as the second material. For example, the third layer G1-1c may include titanium (Ti), but an embodiment of the inventive concept is not limited thereto.

The first layer G1-1a may have a first thickness d1. The second layer G1-1b may have a second thickness d2, and the third layer G1-1c may have a third thickness d3. The second thickness d2 and the third thickness d3 may be substantially the same. The second thickness d2 and the third thickness d3 may be smaller than the first thickness d1.

Referring to FIGS. 5A and 5B, the first upper gate G1-1 may have steps on the uppermost layer due to an etching process to be described later. The first upper gate G1-1 may have the steps on the second layer G1-1b corresponding to the uppermost layer.

The second layer G1-1b may include a lower surface G1-Bb in contact with the first layer G1-1a, and an upper surface G1-Ub opposed to the lower surface G1-Bb. The upper surface G1-Ub of the second layer G1-1b may include a first surface G1-U1, a second surface G1-U2, and a third surface G1-U3 that are separated by the steps. The first surface G1-U1 may be a surface provided between the second surface G1-U2 and the third surface G1-U3. The second surface G1-U2 may be adjacent to a drain region (for example, D1 in FIG. 4) of the metal oxide semiconductor pattern SP, and the third surface G1-U3 may be adjacent to a source region (for example, S1 in FIG. 4) of the metal oxide semiconductor pattern SP. In an embodiment, the second layer G1-1b may be divided into a first part P11 including the second surface G1-U2, a second part P12 including the third surface G1-U3, and a third part P13 including the first surface G1-U1. The third part P13 may include a first side surface G1-S1 and a second side surface G1-S2 that are connected to the first surface G1-U1. The first side surface G1-S1 may be adjacent to the first part P11 and may connect the first surface G1-U1 and the second surface G1-U2 together. The second side surface G1-S2 may be adjacent to the second part P12 and may connect the first surface G1-U1 and the third surface G1-U3 together.

In an embodiment, the second surface G1-U2 and the third surface G1-U3 may each have a lower height than the first surface G1-U1. Therefore, on the upper surface of the second layer G1-1b, the upper surface of the first part P11 and the upper surface of the second part P12 may form the steps with the upper surface of the third part P13, and the third part P13 may have a larger thickness than the first part P11 and the second part P12.

On the second layer G1-1b, the first surface G1-U1 may have a first width W1. The second surface G1-U2 may have a second width W2, and the third surface G1-U3 may have a third width W3. In an embodiment, the first width W1 may be larger than the second width W2 and the third width W3. According to an embodiment of the inventive concept, since the amount of loss in a photoresist pattern, formed on the first gate through an etching process to be described later, is minimized, the second width W2 and the third width W3 may each be significantly smaller than the first width W1. Consequently, the sum of the second width W2 and the third width W3 may be significantly smaller than the first width W1. This structure of the first gate is formed through the etching operation in a manufacturing process of a display device according to an embodiment, to be described later, and through this, the display device DD according to an embodiment may provide excellent display quality.

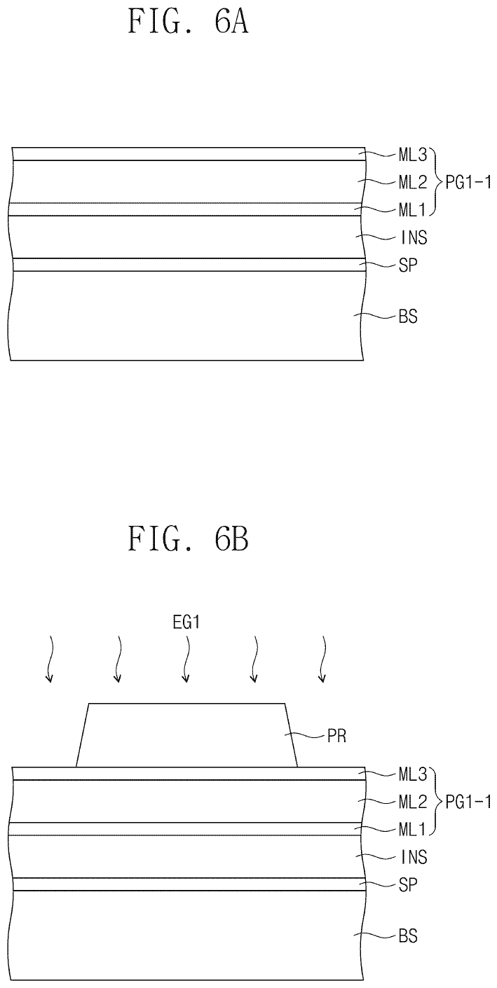

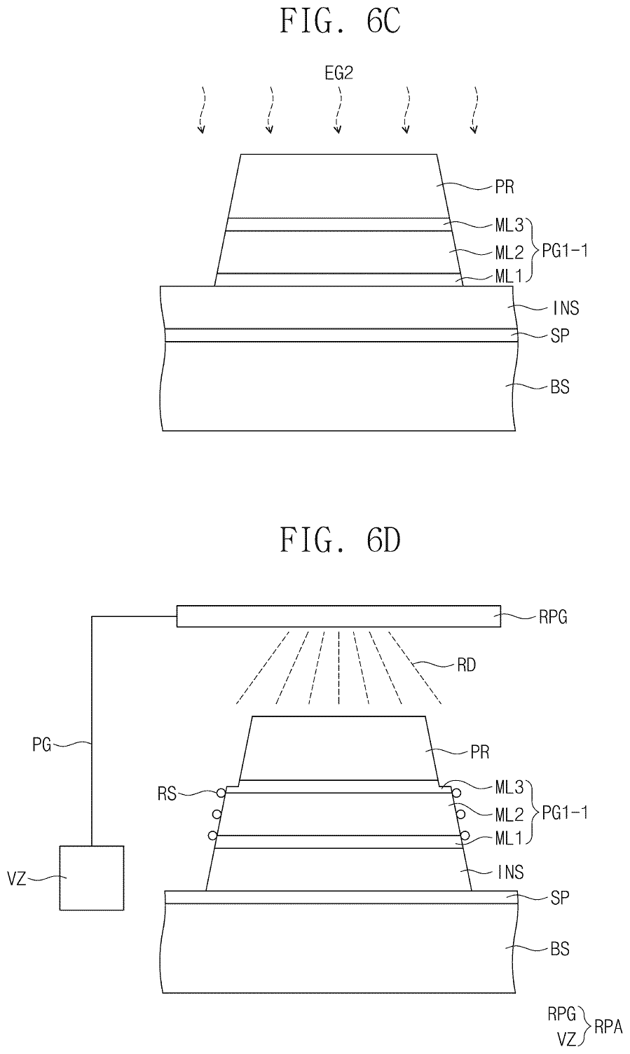

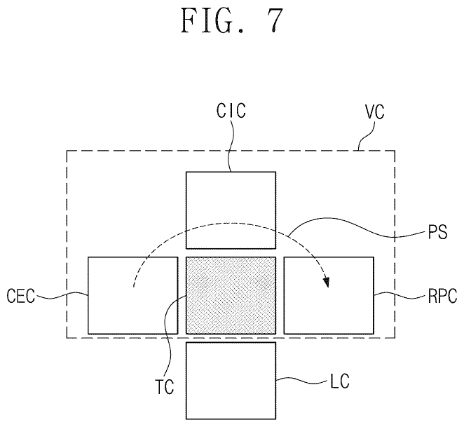

Hereinafter, a method of manufacturing a display panel according to an embodiment of the inventive concept will be described with reference to FIGS. 6A to 6D, and FIG. 7.

The method of manufacturing a display device according to an embodiment may include forming at least one transistor on a base substrate. In an embodiment, the forming of the at least one transistor may include forming a metal oxide semiconductor pattern, forming a preliminary insulation layer, forming a conductive layer, forming a photoresist pattern, forming a first gate, forming a gate insulation pattern, and performing a plasma surface treatment. Through the method of manufacturing the display device according to an embodiment, the display panel DP and the first transistor T1, previously described with reference to FIGS. 3, 4, 5A, and 5B, may be formed.

In the method of manufacturing the display device according to an embodiment, the at least one transistor to be formed on the base substrate may include the first transistor T1 previously described. Accordingly, the previous description of the first transistor T1 may equally apply to the transistor to be formed on the base substrate.

The method of manufacturing the display device according to an embodiment may further include forming a light-emitting element electrically connected to the metal oxide semiconductor pattern. Meanwhile, in the method of manufacturing the display device according to an embodiment, the previous description of the light-emitting element OLED electrically connected to the metal oxide semiconductor pattern SP may equally apply to the light-emitting element.

FIGS. 6A to 6D are cross-sectional views sequentially illustrating some operations of the method of manufacturing the display device according to an embodiment of the inventive concept. FIGS. 6A to 6D exemplarily illustrate the forming of the first transistor T1, previously described, in the method of manufacturing the display device according to an embodiment. Each of FIGS. 6A to 6D illustrates a cross-section corresponding to FIG. 5B by comparison with each other. FIG. 7 is a plan view of a manufacturing process system used in the manufacturing of the display device according to an embodiment. FIG. 7 schematically illustrates the system used in the forming of the first gate in the method of manufacturing the display device.

Referring to FIG. 6A, the forming of the at least one transistor (hereinafter, the forming of the transistor) includes the forming of the metal oxide semiconductor pattern SP on the base substrate BS. For example, the metal oxide semiconductor pattern SP may be formed on the base substrate BS by depositing indium-gallium-zinc oxide (IGZO). The metal oxide semiconductor pattern SP may be formed on the base substrate BS by depositing the indium-gallium-zinc oxide (IGZO) through physical vapor deposition or chemical vapor deposition. The base substrate BS may be a layer including the base layer BL, the barrier layer BRL, and the buffer layer BFL illustrated in FIG. 3, but an embodiment of the inventive concept is not limited thereto.

As illustrated in FIG. 6A, the forming of the transistor may include the forming of the preliminary insulation layer INS on the metal oxide semiconductor pattern SP. The preliminary insulation layer INS may be formed by depositing or coating an insulation material. In this embodiment, the preliminary insulation layer INS may correspond to the first insulation layer 10 illustrated in FIG. 3, but an embodiment of the inventive concept is not limited thereto.

In addition, the forming of the transistor may include the forming of the conductive layer PG1-1 on the preliminary insulation layer INS. The conductive layer PG1-1 may include a first metal layer ML1, a second metal layer ML2, and a third metal layer ML3. The first metal layer ML1 may be formed on the preliminary insulation layer INS. The second metal layer ML2 may be formed on the first metal layer ML1, and the third metal layer ML3 may be formed on the second metal layer ML2.

In an embodiment, the first to third metal layers ML1, ML2, and ML3 may respectively correspond to the third, first, and second layers G1-1c, G1-1a, and G1-1b illustrated in FIG. 5B. For example, the first metal layer ML1 may correspond to the third layer G1-1c, the second metal layer ML2 may correspond to the first layer G1-1a, and the third metal layer ML3 may correspond to the second layer G1-1b.

The first to third metal layers ML1, ML2, and ML3 may each be formed by depositing a conductive material. The first metal layer ML1 may include the aforementioned third material. For example, the third material may include titanium, but an embodiment of the inventive concept is not limited thereto.

The second metal layer ML2 may include the aforementioned first material. The second metal layer ML2 may include a material with a low resistivity. The second metal layer ML2 may have a resistance of about 0.5 Ω or less. The second metal layer ML2 may include a material having a low resistivity of about 3×10⁻⁸ Ω·m or less, and may include, for example, aluminum, but an embodiment of the inventive concept is not limited thereto. The second metal layer ML2 may have a larger thickness than the first metal layer ML1.

The third metal layer ML3 is formed on the second metal layer ML2. The third metal layer ML3 may include the aforementioned second material. The third metal layer ML3 may include the same material as that of the first metal layer ML1. For example, the third metal layer ML3 may include titanium, but an embodiment of the inventive concept is not limited thereto.

In an embodiment, the forming of the transistor may include the forming of the photoresist pattern PR on the conductive layer PG1-1. The photoresist pattern PR may function as a mask in an etching process to be described later.

Although not illustrated in the drawing, in the forming of the photoresist pattern PR, a photoresist layer may be formed by applying a photoresist material onto the conductive layer PG1-1, and then, through an exposure process, the photoresist layer may be patterned to form the photoresist pattern PR. The photoresist material may be a negative-type photoresist material, or a positive-type photoresist material.

Referring to FIG. 6B, the forming of the transistor may include the forming of the first gate. The first gate may be formed from the conductive layer PG1-1. In an embodiment, the first gate may be formed through a first etching process in which the conductive layer PG1-1 is dry-etched by providing a first etching gas EG1. In the first etching process, a portion of the conductive layer PG1-1 not covered by the photoresist pattern PR, which is used as a mask, may be etched by the first etching gas EG1. In an embodiment, the first to third metal layers ML1, ML2, and ML3 of the conductive layer PG1-1 may be formed by being patterned simultaneously through one mask that is the photoresist pattern PR. Accordingly, the patterned first to third metal layers ML1, ML2, and ML3 may have side surfaces aligned on a cross-section. That is, the patterned first to third metal layers ML1, ML2, and ML3 may have the side surfaces forming a continuous slope. However, this is an example, and the first to third metal layers ML1, ML2, and ML3 may have the side surfaces misaligned on a cross-section.

The first etching gas EG1 may include a chlorine-based gas for improving etching efficiency. The chlorine-based gas may include at least one of a chlorine (Cl₂) gas or a boron trichloride (BCl₃) gas. At this time, the chlorine-based gas which is provided as the first etching gas EG1 may remain on a surface of the first gate in the form of chloride ion (Cl⁻), and the chloride ion (Cl⁻) may cause corrosion of the first gate. For example, the chloride ion (Cl⁻) included in the first etching gas EG1 may form a by-product such as AlClₓ in response to aluminum included in the second metal layer ML2, and cause corrosion of the first gate. Therefore, the method of manufacturing the display device according to an embodiment of the inventive concept may include removing chloride ion (Cl⁻). The chloride ion (Cl⁻) may be removed through a plasma post-treatment device RPA (see FIG. 6D), and the removing of the chloride ion (Cl⁻) will be described later with reference to FIG. 6D.

Referring to FIG. 6C, the forming of the transistor according to an embodiment of the inventive concept may include the forming of the gate insulation pattern. The gate insulation pattern may be formed from the preliminary insulation layer INS. In an embodiment, the gate insulation pattern may be formed by providing an etching gas to the preliminary insulation layer INS before the performing of the plasma surface treatment. In the performing of the plasma surface treatment, the chloride ion (Cl⁻) may be removed through the plasma post-treatment device RPA (see FIG. 6D) that provides a water vapor (H₂O) plasma, and in this process, a portion of the photoresist pattern PR may be lost due to the water vapor (H₂O) plasma. In the method of manufacturing the display device according to an embodiment, since the preliminary insulation layer INS is etched before the performing of the plasma surface treatment, it may be possible to form the gate insulation pattern with the minimum amount of loss in the photoresist pattern PR. Accordingly, the amount of by-products deposited on the surface of the gate insulation pattern may be significantly reduced, thereby preventing leakage current from occurring between the first gate and the metal oxide semiconductor pattern SP. The by-product may be a non-volatile material such as TiFₓ generated due to damage to the uppermost layer of the first gate, for example, the third metal layer ML3, by the etching gas, but an embodiment of the inventive concept is not limited thereto.

The gate insulation pattern may be formed through a second etching process in which the preliminary insulation layer INS is dry-etched by providing a second etching gas EG2. In the process for dry etching the gate insulation pattern, using the photoresist pattern PR, and the conductive layer PG1-1 which has been etched through the first etching process, as masks, a portion of the preliminary insulation layer INS not covered by the photoresist pattern PR and the conductive layer PG1-1 may be etched by the second etching gas EG2. In an embodiment, the etched conductive layer PG1-1 and preliminary insulation layer INS may have side surfaces aligned on a cross-section. For example, the etched conductive layer PG1-1 and preliminary insulation layer INS may have the side surfaces forming a continuous slope.

In an embodiment, the preliminary insulation layer INS may include silicon oxide (SiOₓ). Accordingly, the second etching gas EG2 may be different from the first etching gas EG1 (see FIG. 6B) used in the first etching process. The second etching gas EG2 may include a tetrafluoromethane (CF₄) gas and oxygen (O₂) gas. The preliminary insulation layer INS, which is etched by using the tetrafluoromethane (CF₄) gas and the oxygen (O₂) gas, may have an excellent etch profile in terms of uniformity, a side slope angle, etc. Meanwhile, the second etching gas EG2 is not necessarily limited to the tetrafluoromethane (CF₄) gas or the oxygen (O₂) gas, and the type may vary according to aluminum oxide, titanium oxide, silicon nitride, silicon oxynitride, zirconium oxide, hafnium oxide, etc. included in the preliminary insulation layer INS.

Referring to FIG. 6D, the forming of the transistor according to an embodiment of the inventive concept may include the removing of chloride ion (Cl⁻). The removing of the chloride ion (Cl⁻) may be the performing of the plasma surface treatment on the first gate, the gate insulation pattern, and the photoresist pattern PR. The plasma surface treatment is for preventing corrosions of the first to third metal layers ML1, ML2, and ML3 and the preliminary insulation layer INS that are etched through the first and second etching processes, and may be performed on the first gate and the gate insulation pattern formed after the first and second etching processes, and on the photoresist pattern PR.

For example, after the first etching process, by-products RS including chloride ion (Cl⁻) may remain on the surface of the conductive layer PG1-1 not covered by the photoresist pattern PR. Since the chloride ion (Cl⁻) may cause corrosion of the first gate, in the forming of the transistor according to an embodiment, the by-products RS may be removed by performing the surface treatment on the first gate, the gate insulation pattern, and the photoresist pattern PR through the plasma post-treatment device RPA.

In an embodiment, the plasma post-treatment device RPA may include a process gas generator VZ and a plasma generating device RPG. The process gas generator VZ and the plasma generating device RPG may be connected through a gas pipeline PG. The process gas generator VZ may generate a process gas, and provide the process gas to the plasma generating device RPG through the gas pipeline PG. The process gas provided to the plasma generating device RPG may be water vapor H₂O. Although not illustrated in the drawing, the plasma post-treatment device RPA may be disposed in a chamber. The chamber may provide a space for the plasma surface treatment process to be performed. An inner space of the chamber may be tightly closed from the outside during the plasma surface treatment process. The chamber may include at least one outlet for discharging the gas inside.

For example, the plasma generating device RPG may receive water vapor from the process gas generator VZ to generate plasma. The plasma generating device RPG may generate a large amount of radical RD of plasma to be provided to the etched conductive layer PG1-1, the etched preliminary insulation layer INS, and the photoresist pattern PR. The radical RD may include OH, H, or O, and may be sprayed from the plasma generating device RPG to the entire region of an upper surface of the base substrate BS on which the conductive layer PG1-1, the preliminary insulation layer INS, etc. are disposed. In an embodiment, the radical RD is coupled to the chloride ion (Cl⁻) remaining on the surface of the etched conductive layer PG1-1, etc. and discharged to the outside of the chamber in the form of hydrochloric acid (HCl). In addition, the radical RD may contribute to improving ashing capability for removing the photoresist pattern PR in a following process.

Although not illustrated in the drawing, the forming of the transistor may further include removing the photoresist pattern PR after the performing of the plasma surface treatment. The photoresist pattern PR may be removed through a wet-etching process by providing an etching solution. In addition, the forming of the transistor may further include cleaning the surface of the first gate after the first and second etching processes and the performing of the plasma surface treatment.

Referring to FIG. 7, the forming of the transistor previously described may be performed through a single system (1 system) process. The single system (1 system) process may be formed through a process system VC. The process system VC may have an inner space defined therein for the first etching process, the second etching process, and the plasma surface treatment process to be performed. The process system VC may be a vacuum chamber, and may include first to third chambers CEC, CIC, and RPC and a transfer chamber TC.

In an embodiment, in the single system (1 system) process, the aforementioned first and second etching processes and the plasma surface treatment process may be performed in the first to third chambers CEC, CIC, and RPC. The single system process may proceed along a first proceeding direction PS. The first proceeding direction PS may mean that the process proceeds in the order of the first chamber CEC, the second chamber CIC, and the third chamber RPC. For example, the first etching process for forming the first gate may be performed in the first chamber CEC. The second etching process for forming the gate insulation pattern may be performed in the second chamber CIC. In addition, the plasma surface treatment process for applying a surface treatment onto the first gate, etc. may be performed in the third chamber RPC. In addition, the movement between the first to third chambers CEC, CIC, and RPC may be made through the transfer chamber TC.

In the single system (1 system) process, the first etching process, the second etching process, and the surface treatment process may be performed in respectively different chambers in the same equipment, and the processes may continue without vacuum break through a load lock system LC between the first to third chambers CEC, CIC, and RPC.

In the method of manufacturing the display device according to an embodiment of the inventive concept, the plasma surface treatment process for preventing corrosion of the first gate may be performed after the first etching process for forming the first gate and the second etching process for forming the gate insulation pattern. Accordingly, the amount of loss in the photoresist pattern PR may be reduced, thereby preventing the by-products RS containing chloride ion from remaining on the surfaces of the first gate and the gate insulation pattern. Therefore, in the method of manufacturing the display device according to an embodiment, occurrence of leakage current between the metal oxide semiconductor pattern SP and the first gate is prevented, and thus, it may be possible to manufacture the display device with improved display quality and reliability.

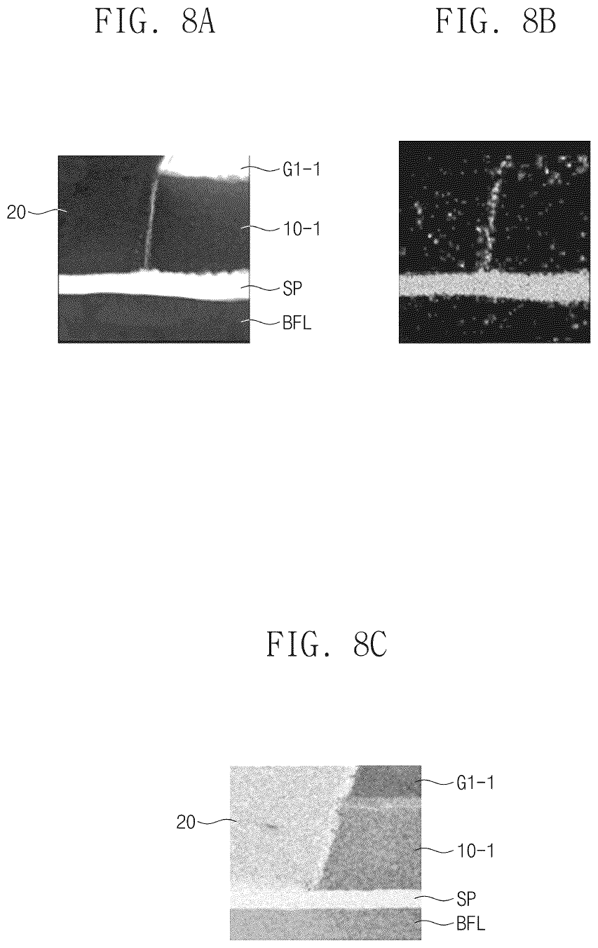

Table 1 and FIGS. 8A to 10B are evaluation results of a display device formed by a method of manufacturing a display device according to an embodiment of the inventive concept, and a display device formed by a manufacturing method according to a comparative example. In Table 1, an Example corresponds to a transistor manufactured by performing the first and second etching processes in order and then performing the plasma surface treatment, and a display device including the transistor. In particular, the Example corresponds to the transistor manufactured along the process order described with reference to FIGS. 6A to 6D, and the display device including the transistor.

Meanwhile, in Table 1, a Comparative Example corresponds to a transistor manufactured by a method of manufacturing a display device different from the Example in the process order, and a display device including the transistor. In the Comparative Example, the aforementioned first etching process is performed, then the plasma surface treatment process is performed, and then the second etching process is performed. In the Example and the Comparative Example of Table 1, all other conditions, except for the process order, are the same in the processes.

FIGS. 8A to 8C are images showing results of TiFx contamination evaluation for the Comparative Example and the Example. FIGS. 8A and 8B are TEM images for the transistor of the Comparative Example, and FIG. 8C is a TEM image for the transistor of the Example.

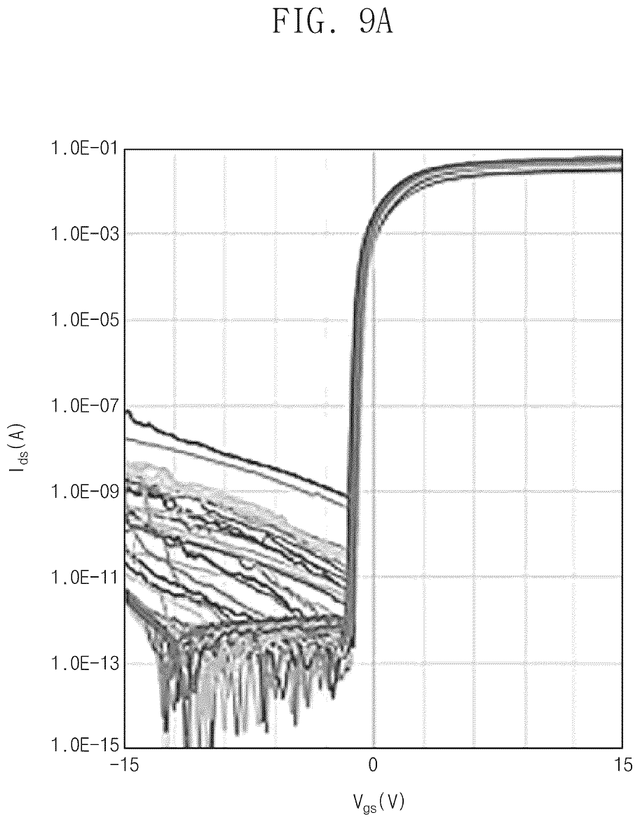

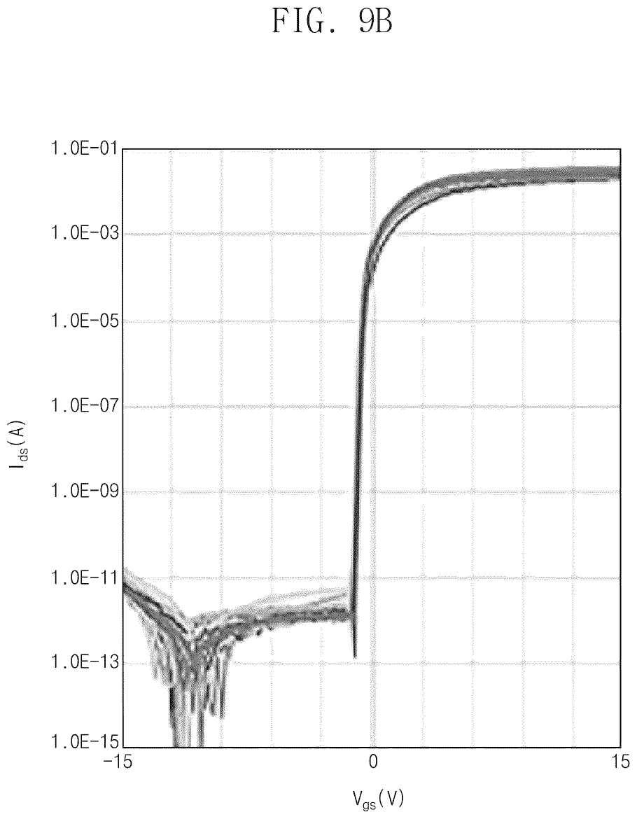

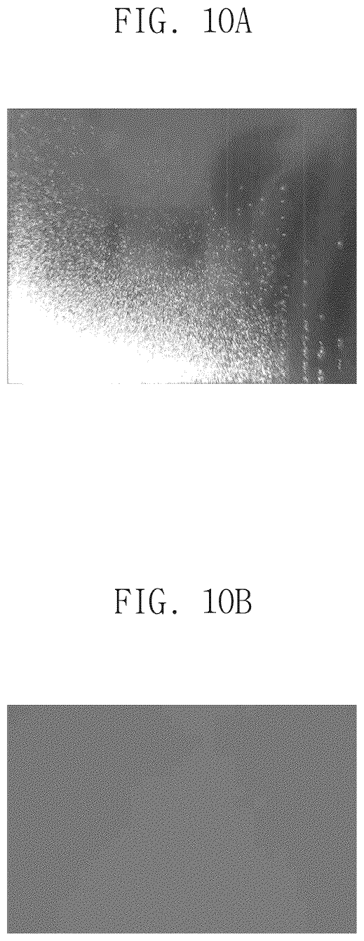

FIGS. 9A and 9B are graphs respectively showing results of leakage current evaluation for the Comparative Example and the Example. FIG. 9A is a graph showing voltage-current characteristics of the Comparative Example, and FIG. 9B is a graph showing voltage-current characteristics of the Example. FIGS. 10A and 10B are images respectively showing results of bright spot defect evaluation for the Comparative Example and the Example. FIG. 10A is an image showing the result of bright spot defect evaluation for the Comparative Example, and FIG. 10B is an image showing the result of bright spot defect evaluation for the Example.

TABLE 1

| | Measurement | Comparative Example | Example |
|---|---|---|---|
| Process order | — | First etching process- | First etching process-Second |
| | | Plasma surface treatment | etching process-Plasma |
| | | process-Second etching | surface treatment process |
| | | process | |
| TiFₓ | TEM | Occurred | Not occurred |
| contamination | | | |
| Leakage current | DC measurement | Occurred | Not occurred |
| Bright spot defect | Panel lighting | Occurred | Not occurred |

Referring to Table 1, FIGS. 8A, 8B, 9A, and 10A, it is seen that in the display device of the Comparative Example, the transistor has the TiFₓ contamination occurred on the surface thereof, and the leakage current occurs between the metal oxide semiconductor pattern and the first gate, thereby generating bright spot defects.

Compared to this, referring to Table 1, FIGS. 8C, 9B, and 10B, it may be seen that in the display device of the Example, manufactured in a way that the first etching process and the second etching process are performed and then the plasma surface treatment is performed according to an embodiment of the inventive concept, the transistor has no TiFₓ contamination occurred on the surface thereof, and thus the leakage current between the metal oxide semiconductor pattern and the first gate does not occur. Therefore, it is seen that the display device of Example has no bright spot defect occurred.

According to a method of manufacturing a display device according to an embodiment, by reducing the amount of loss in photoresist in a gate etching process, it may be possible to prevent by-products from being attached onto surfaces of a gate and a gate insulation layer, and thus prevent leakage current from occurring between an oxide semiconductor pattern and the gate, thereby manufacturing a display device with improved display quality and reliability.

The display device according to an embodiment may provide excellent display quality through the aforementioned method of manufacturing a display device.

Although the embodiments of the present invention have been described, it is understood that the present invention should not be limited to these embodiments but various changes and modifications can be made by one ordinary skilled in the art within the spirit and scope of the present invention as hereinafter claimed.

Therefore, the scope of the inventive concept should not be limited to the contents described in the detailed description of the specification, but should be defined by the claims.

What is claimed is:

1. A display device comprising:
a base layer;
a light-emitting element disposed on the base layer; and
a pixel circuit disposed between the base layer and the light-emitting element, and electrically connected to the light-emitting element,
wherein the pixel circuit includes a first transistor,
the first transistor includes
a metal oxide semiconductor pattern having a drain region, a source region, and a channel region disposed between the source region and the drain region,
a first gate disposed on the metal oxide semiconductor pattern, overlapping the channel region, and having a plurality of conductive layers, and
a gate insulation pattern disposed between the metal oxide semiconductor pattern and the first gate, and overlapping the channel region,
an uppermost layer among the plurality of conductive layers is divided into a first part adjacent to the drain region, a second part adjacent to the source region, and a third part between the first part and the second part,
each of an upper surface of the first part and an upper surface of the second part forms a step with an upper surface of the third part, and
on a cross-section perpendicular to the base layer, a sum of widths of the upper surface of the first part and the upper surface of the second part in one direction is smaller than a width of the upper surface of the third part in the one direction.

2. The display device of claim 1, wherein a side surface of the first gate and a side surface of the gate insulation pattern form a continuous slope.

3. The display device of claim 1, wherein a thickness of the third part is larger than a thickness of each of the first part and the second part.

4. The display device of claim 1, wherein the first gate comprises:
a first layer disposed on the gate insulation pattern, and including a first material; and
a second layer disposed on the first layer, and including a second material different from the first material,
the first material having lower resistivity than the second material.

5. The display device of claim 4, wherein the first material comprises aluminum, and the second material comprises titanium.

6. The display device of claim 4, wherein the first gate further comprises a third layer disposed between the gate insulation pattern and the first layer, and including a third material different from the first material,
the third material having higher resistivity than the first material.

7. The display device of claim 6, wherein the first material comprises aluminum, and each of the second material and the third material comprises titanium.

8. The display device of claim 6, wherein the first layer has a larger thickness than the second layer and the third layer.

9. The display device of claim 1, wherein the third part comprises a first side surface adjacent to the first part, and a second side surface adjacent to the second part,
the first side surface connects the upper surface of the first part and the upper surface of the third part, and
the second side surface connects the upper surface of the second part and the upper surface of the third part.

10. A method of manufacturing a display device, comprising forming at least one transistor on a base substrate,
wherein the forming of the at least one transistor includes:
forming a metal oxide semiconductor pattern on the base substrate;
forming a preliminary insulation layer on the metal oxide semiconductor pattern;
forming a conductive layer having an aluminum layer on the preliminary insulation layer;
forming a photoresist pattern on the conductive layer;
forming a first gate from the conductive layer by using a first etching gas containing a chlorine-based gas;
forming a gate insulation pattern from the preliminary insulation layer by using a second etching gas different from the first etching gas; and
performing a plasma surface treatment on the first gate, the gate insulation pattern, and the photoresist pattern.

11. The method of claim 10, wherein the first etching gas comprises at least one of a chlorine (Cl₂) gas or a boron trichloride (BCl₃) gas.

12. The method of claim 10, wherein the second etching gas comprises a tetrafluoromethane (CF₄) gas and an oxygen (O₂) gas.

13. The method of claim 10, wherein in the performing of the plasma surface treatment, a chlorine-containing residue is removed from surfaces of the first gate, the gate insulation pattern, and the photoresist pattern.

14. The method of claim 13, further comprising removing the photoresist pattern after the performing of the plasma surface treatment.

15. The method of claim 10, further comprising forming a light-emitting element which is electrically connected to the metal oxide semiconductor pattern.

16. The method of claim 10, wherein the forming of the conductive layer comprises:
forming a first metal layer on the preliminary insulation layer;
forming a second metal layer on the first metal layer; and
forming a third metal layer on the second metal layer, and
the second metal layer is the aluminum layer, and has lower resistivity than the first metal layer and the third metal layer.

17. The method of claim 16, wherein each of the first metal layer and the third metal layer is a titanium layer.

18. The method of claim 16, wherein in the forming of the first gate, at least a portion of an upper surface of the third metal layer is exposed.

19. The method of claim 18, wherein the metal oxide semiconductor pattern comprises a source region, a drain region, and a channel region disposed between the source region and the drain region,
the third metal layer is divided into a first part adjacent to the drain region, a second part adjacent to the source region, and a third part between the first part and the second part, and
each of an upper surface of the first part and an upper surface of the second part forms a step with an upper surface of the third part.

20. The method of claim 19, wherein on a cross-section perpendicular to the base substrate, a sum of widths of the upper surface of the first part and the upper surface of the second part in one direction is smaller than a width of the upper surface of the third part in the one direction.
